(19) United States
(12) Patent Application Publication
(10) Pub. No.: US 2026/0293288 A1
(43) Pub. Date: Sep. 24, 2026

(54) SEMICONDUCTOR DEVICE

(71) Applicant: Mitsubishi Electric Corporation, Tokyo (JP)

(72) Inventors: Kakeru OTSUKA, Tokyo (JP); Masaki SUDO, Tokyo (JP); Kazuya KONISHI, Tokyo (JP)

(73) Assignee: Mitsubishi Electric Corporation, Tokyo (JP)

(21) Appl. No.: 19/351,205

(22) Filed: Oct. 6, 2025

(30) Foreign Application Priority Data
Mar. 24, 2025 (JP) 2025-047839

(51) Int. Cl. H10D 84/00; H10D 12/00; H10D 62/10; H10D 62/83; H10D 62/832; H10D 62/85; H10D 64/00

(52) U.S. Cl. CPC H10D 84/161; H10D 12/212; H10D 12/481; H10D 62/103; H10D 62/124; H10D 62/8303; H10D 62/8325; H10D 62/8503; H10D 12/415; H10D 64/112; H10D 64/117

(57) ABSTRACT

A semiconductor device according to the present disclosure includes a semiconductor substrate having an IGBT region and a diode region, the IGBT region having an upper surface on which one or more IGBT trenches are formed, the diode region having an upper surface on which one or more diode trenches are formed, a front surface electrode, a back surface electrode, IGBT gate electrodes provided inside the respective IGBT trenches and diode gate electrodes provided inside the respective diode trenches, wherein the diode trenches are deeper than an anode layer of the diode region, and (WDT×N)/WD≤0.13 is satisfied, where WD is a width of the diode region in a direction in which the IGBT region and the diode region are aligned, WDT is a width of one of the diode trenches, and N is the number of the diode trenches.

### BACKGROUND

### Field

The present disclosure relates to a semiconductor device.

### Background

JP 2022-56498 A discloses an RC-IGBT (reverse conducting-insulated gate bipolar transistor). In the RC-IGBT, the IGBT and freewheeling diode are formed on a single semiconductor substrate. In JP 2022-56498 A, no trench is formed in the diode region, thus on voltage is reduced.

In JP 2022-56498 A, the trench is completely eliminated in the diode region, thereby the voltage VF can be reduced when the diode is energized. However, there is a problem in which the electric field strength becomes high at the lower part of the trench at the end of the IGBT region, and the withstand voltage decreases.

### SUMMARY

The present disclosure has been made to solve the above-mentioned problem, and an object thereof is to provide a semiconductor device capable of preventing a decrease in withstand voltage while improving current-carrying capacity.

The features and advantages of the present disclosure may be summarized as follows.

According to an aspect of the present disclosure, a semiconductor device includes a semiconductor substrate having an IGBT region and a diode region, the IGBT region having an upper surface on which one or more IGBT trenches are formed, the diode region having an upper surface on which one or more diode trenches are formed, a front surface electrode provided on an upper surface of the semiconductor substrate, a back surface electrode provided on a back surface of the semiconductor substrate, IGBT gate electrodes provided inside the respective IGBT trenches and diode gate electrodes provided inside the respective diode trenches, wherein the diode trenches are deeper than an anode layer of the diode region, and (WDT×N)/WD≤0.13 is satisfied, where WD is a width of the diode region in a direction in which the IGBT region and the diode region are aligned, WDT is a width of one of the diode trenches, and N is the number of the diode trenches.

According to an aspect of the present disclosure, a semiconductor device includes a semiconductor substrate having an IGBT region, a diode region, and a boundary region between the IGBT region and the diode region, the IGBT region having an upper surface on which one or more IGBT trenches are formed, the diode region having an upper surface on which no trench gate structure is formed, a front surface electrode provided on an upper surface of the semiconductor substrate, a back surface electrode provided on a back surface of the semiconductor substrate and IGBT gate electrodes provided inside the respective IGBT trenches, wherein a plurality of boundary trenches are formed on an upper surface of the boundary region, and the plurality of boundary trenches satisfies one or more of the following: a trench closest to the diode region is shallower than a trench closest to the IGBT region; a trench closest to the diode region is narrower than a trench closest to the IGBT region; and a pitch of the boundary trenches is different from a pitch of the IGBT trenches.

According to an aspect of the present disclosure, a semiconductor device includes a semiconductor substrate having an IGBT region and a diode region, the IGBT region having an upper surface on which one or more IGBT trenches are formed, the diode region having an upper surface on which no trench gate structure is formed, a front surface electrode provided on an upper surface of the semiconductor substrate, a back surface electrode provided on a back surface of the semiconductor substrate and IGBT gate electrodes provided inside the respective IGBT trenches, wherein an anode layer of the diode region is provided so as to cover a lower end of a trench provided closest to the diode region among the IGBT trenches.

Other and further objects, features and advantages of the disclosure will appear more fully from the following description.

### BRIEF DESCRIPTION OF DRAWINGS

FIG. 1 is a plan view of a semiconductor device according to a first embodiment.

FIG. 2 is an enlarged view of region A1 in FIG. 1.

FIG. 3 is a cross-sectional view obtained by cutting FIG. 2 along line A-B.

FIG. 4 is a diagram showing the relationship between (WDT×N)/WD and VF.

FIG. 5 is a cross-sectional view of a semiconductor device according to the second embodiment.

FIG. 6 is a cross-sectional view of a semiconductor device according to a third embodiment.

FIG. 7 is a cross-sectional view of a semiconductor device according to a fourth embodiment.

FIG. 8 is a cross-sectional view of a semiconductor device according to a fifth embodiment.

FIG. 9 is a cross-sectional view of a semiconductor device according to a sixth embodiment.

FIG. 10 is a cross-sectional view of a semiconductor device according to a seventh embodiment.

FIG. 11 is a cross-sectional view of a semiconductor device according to an eighth embodiment.

FIG. 12 is a cross-sectional view of a semiconductor device according to a nineth embodiment.

FIG. 13 is a cross-sectional view of a semiconductor device according to a tenth embodiment.

FIG. 14 is a cross-sectional view of a semiconductor device according to an eleventh embodiment.

FIG. 15 is a cross-sectional view of a semiconductor device according to a twelfth embodiment.

FIG. 16 is a cross-sectional view of a semiconductor device according to a thirteenth embodiment.

FIG. 17 is a cross-sectional view of a semiconductor device according to a fourteenth embodiment.

FIG. 18 is an enlarged view of FIG. 17.

FIG. 19 is a cross-sectional view of a semiconductor device according to a fifteenth embodiment.

FIG. 20 is a plan view of a semiconductor device according to a sixteenth embodiment.

FIG. 21 is a plan view of a semiconductor device according to a seventeenth embodiment.

FIG. 22 is a cross-sectional view of a semiconductor device according to an eighteenth embodiment.

FIG. 23 is a cross-sectional view of a semiconductor device according to a nineteenth embodiment.

FIG. 24 is a cross-sectional view of a semiconductor device according to a twentieth embodiment.

FIG. 25 is a plan view of a semiconductor device according to a twenty-first embodiment.

FIG. 26 is an enlarged view of FIG. 25.

FIG. 27 is a plan view of a semiconductor device according to a modification of the twenty-first embodiment.

FIG. 28 is a cross-sectional view of a semiconductor device according to a twenty-second embodiment.

FIG. 29 is a plan view of an IGBT region according to a twenty-third embodiment.

FIG. 30 is a plan view of a diode region according to the twenty-third embodiment.

FIG. 31 is a plan view of a semiconductor device according to a twenty-fourth embodiment.

FIG. 32 is a cross-sectional view of a semiconductor device according to a twenty-fifth embodiment.

FIG. 33 is a cross-sectional view of a semiconductor device according to a twenty-sixth embodiment.

FIG. 34 is a cross-sectional view of a semiconductor device according to a twenty-seventh embodiment.

FIG. 35 is a cross-sectional view of a semiconductor device according to a twenty-eighth embodiment.

### DESCRIPTION OF EMBODIMENTS

A semiconductor device according to each embodiment will be described with reference to the accompanying drawings. Components identical or corresponding to each other are indicated by the same reference characters, and repeated description of them is avoided in some cases.

### First Embodiment

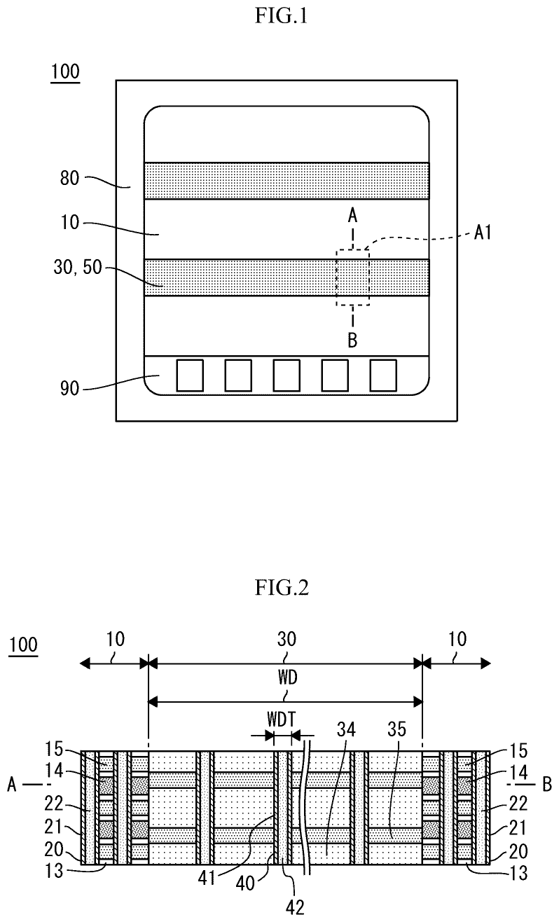

FIG. 1 is a plan view of a semiconductor device 100 according to a first embodiment. The semiconductor device 100 is an RC-IGBT. The semiconductor device 100 includes a cell region and a termination region 80 surrounding the cell region. In the cell region, a semiconductor substrate has, for example, IGBT regions 10 and diode regions 30 alternately provided thereon. Note that, as described below, a boundary region 50 may be provided between the IGBT region 10 and the diode region 30. In this embodiment, the boundary region 50 is not essential. A signal pad region 90 is provided between the cell region and the termination region 80. The IGBT region 10 and the diode region 30 may be positioned optionally. For example, one of the IGBT region 10 and the diode region 30 may be provided so as to surround the other.

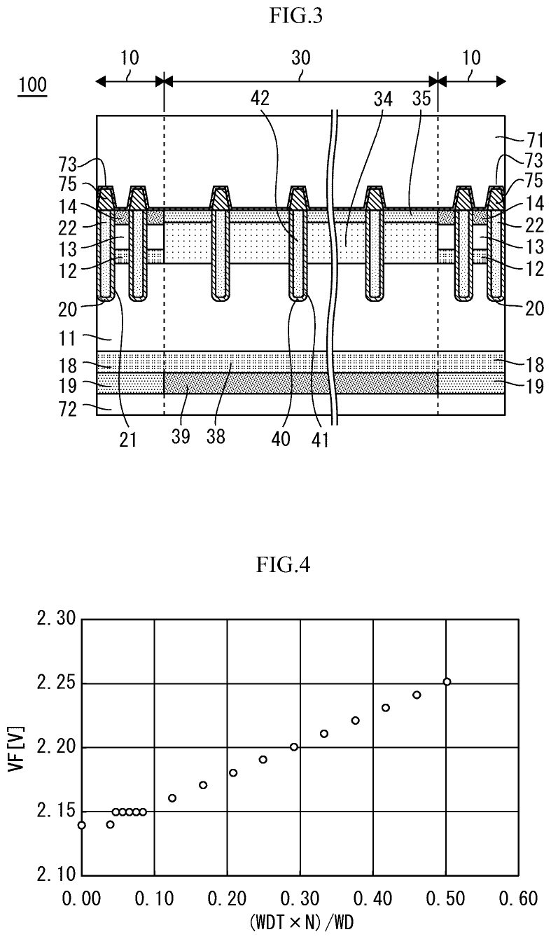

FIG. 2 is an enlarged view of region A1 in FIG. 1. FIG. 3 is a cross-sectional view obtained by cutting FIG. 2 along line A-B. In the following description, N-type is referred to as a first conductivity type and P-type is referred to as a second conductivity type, but P-type may be a first conductivity type and N-type may be a second conductivity type.

A drift layer 11 of N-type is formed in the semiconductor substrate. The semiconductor substrate is, for example, a silicon substrate. In the IGBT regions 10, an N-type carrier accumulation layer 12 is formed on the upper surface side of the drift layer 11. A base layer 13 of P-type is formed on the upper surface side of the carrier accumulation layer 12. An emitter layer 14 of N+ type is formed on the upper surface side of the base layer 13. Note that, as shown in FIG. 2, the emitter layers 14 and IGBT contact layers 15 of P+ type are selectively provided on the uppermost surface of the semiconductor substrate in the IGBT regions 10. The IGBT contact layer 15 does not appear in the cross section shown in FIG. 3. In the IGBT regions 10, a buffer layer 18 of N-type is formed on the back surface side of the drift layer 11. A collector layer 19 of P-type is formed on the back surface side of the buffer layer 18.

In the diode region 30, an anode layer 34 of P-type is formed on the upper surface side of the drift layers 11. A diode contact layer 35 of P+ type is formed on the upper surface side of the anode layer 34. Note that, as shown in FIG. 2, the anode layers 34 and the diode contact layers 35 are selectively provided on the uppermost surface of the semiconductor substrate in the diode region 30. In the diode region 30, a buffer layer 38 of N-type is formed on the back surface side of the drift layer 11. A cathode layer 39 of N-type is formed on the back surface side of the buffer layer 38. The cathode layer 39 may be formed over the entire surface, or may be thinned out and formed discretely.

One or more IGBT trenches 20 are formed on the upper surface of each IGBT region 10. An IGBT gate insulating film 21 is formed on the inner wall of each IGBT trench 20. An IGBT gate electrode 22 is provided inside the IGBT trench 20 via the IGBT gate insulating film 21 interposed therebetween. The IGBT gate electrodes 22 are made of, for example, polysilicon. The plurality of IGBT trenches 20 are provided in a stripe pattern.

One or more diode trenches 40 are formed on the upper surface of the diode region 30. A diode gate insulating film 41 is formed on the inner wall of each diode trench 40. A diode gate electrode 42 is provided inside the diode trench 40 via the diode gate insulating film 41. The diode gate electrode 42 is made of, for example, polysilicon. The plurality of diode trenches 40 are provided in a stripe pattern. The diode trenches 40 of this embodiment are deeper than the anode layer 34.

An insulating interlayer film 75 is provided on each of the IGBT trench 20 and the diode trench 40. A front surface electrode 71 is provided on the upper surface of the semiconductor substrate and on the insulating interlayer film 75, via a barrier metal 73. The front surface electrode 71 is an emitter electrode or an anode electrode. A back surface electrode 72 is provided on the back surface of the semiconductor substrate. The back surface electrode 72 is a collector electrode or a cathode electrode.

The IGBT gate electrodes 22 and the diode gate electrodes 42 are electrically connected to the gate pad in the signal pad region 90. In other words, a MOS (metal-oxide-semiconductor) structure controlled by the IGBT gate electrodes 22 is formed on the upper surface side of the IGBT regions 10.

Next, the diode trenches 40 are to be described in detail. The width of the diode region 30 in the direction in which the IGBT regions 10 and the diode region 30 are aligned is defined as WD. The width of one diode trench 40 is defined as WDT. The number of diode trenches 40 in one diode region 30 is defined as N. In the example of FIGS. 2 and 3, N=3, but N only needs to be 1 or more. The semiconductor device 100 of this embodiment satisfies (WDT×N)/WD≤0.13.

FIG. 4 is a diagram showing the relationship between (WDT×N)/WD and VF. This demonstrates that VF decreases with decreasing (WDT×N)/WD, and VF is constant when (WDT×N)/WD≤0.13. As shown in FIG. 4, a low VF can be obtained when (WDT×N)/WD 0.13, making it possible to improve the current-carrying capacity of the diode region 30. Note that, if the diode trenches 40 are shallower than the anode layer 34, the dependence shown in FIG. 4 cannot be obtained. In addition, even if the anode concentration is changed, the inflection point of (WDT×N)/WD does not change.

Conventionally, the voltage VF when the diode is energized is reduced by eliminating the diode trench. However, eliminating the diode trench raises a problem of increased electric field strength at the lower part of the trench at the end of the IGBT region, resulting in decreased withstand voltage. In addition, conventionally, dummy trenches have been placed in the diode region to reduce the effective region of the anode layer surface. In this case, VF may worsen.

In contrast, in this embodiment, the diode trenches 40 is left, thereby making it possible to prevent a decrease in the withstand voltage. Furthermore, (WDT×N)/WD≤0.13 is satisfied, thereby making it possible to reduce VF. Therefore, it is possible to improve the current-carrying capacity while preventing a decrease in the withstand voltage. In other words, the number of trenches positioned in the diode region 30 can be effectively reduced.

Note that in this embodiment, (WDT×N)/WD≤0.13 is used, but depending on the desired VF value, (WDT×N)/WD<0.10 or (WDT×N)/WD<0.04 may also be used. The pitch of the diode trenches 40 does not have to be constant.

Furthermore, the structure of the semiconductor device 100 is an example, and some layers may be omitted. For example, the carrier accumulation layer 12 may be omitted. The semiconductor substrate may also be made of a wide bandgap semiconductor. The wide bandgap semiconductor is silicon carbide, a gallium nitride-based material, or diamond.

These modifications can be appropriately applied to semiconductor devices according to embodiments below. Meanwhile, for the semiconductor devices according to the embodiments below, dissimilarities with the first embodiment will mainly be explained as they have many similarities with the first embodiment.

### Second Embodiment

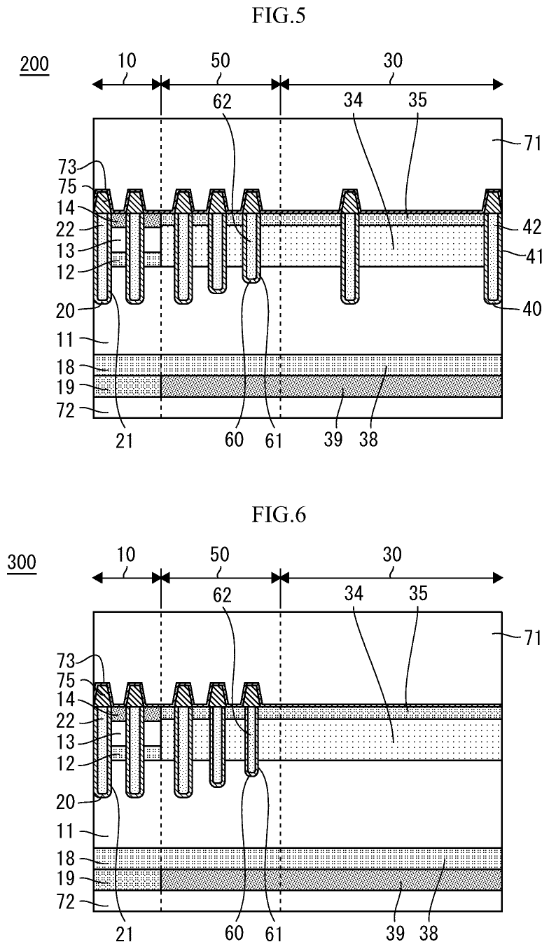

FIG. 5 is a cross-sectional view of a semiconductor device 200 according to the second embodiment. This embodiment differs from the first embodiment in that the semiconductor substrate has a boundary region 50 between the IGBT region 10 and the diode region 30. A plurality of boundary trenches 60 are formed on the upper surface of the boundary region 50. A boundary gate insulating film 61 is formed on the inner wall of each boundary trench 60. A boundary gate electrode 62 is provided inside the boundary trench 60 via the boundary gate insulating film 61. The boundary gate electrode 62 is made of, for example, polysilicon. The plurality of boundary trenches 60 are provided in a stripe pattern. The boundary gate electrodes 62 are electrically connected to the gate pad in the signal pad region 90.

The boundary region 50 is a region where boundary trenches 60 are positioned for the purpose of relaxing the electric field. Forming the boundary trenches 60 in the boundary region 50 can prevent a decrease in withstand voltage compared to a case in which the boundary trench 60 is not present. The plurality of boundary trenches 60 and the IGBT trenches 20 may differ in at least one of, for example, trench pitch, depth, and width. As a result, this embodiment can also improve current-carrying capacity while preventing a decrease in withstand voltage.

In this embodiment, at least one boundary trench 60 needs to be provided. In addition, the features of the following embodiments can also be applied to this embodiment. The depth of the IGBT trenches 20 and the diode trenches 40 are, for example, the same depth as the deepest trench of the boundary trenches 60.

### Third Embodiment

FIG. 6 is a cross-sectional view of a semiconductor device 300 according to a third embodiment. This embodiment differs from the second embodiment in that no trench gate structure is formed on the upper surface of the semiconductor substrate in the diode region 30. That no trench gate structure is formed means that no trench such as the diode trench 40, in which a diode gate electrode 42 connected to a gate pad is provided, is formed. Note that, in the diode region 30, the diode trenches 40 and the dummy trenches as in the first and the second embodiments do not have to be formed.

In this embodiment, since no trench gate structure is formed in the diode region 30, VF can be reduced and current-carrying capacity can be improved. Furthermore, forming the boundary trenches 60 in the boundary region 50 can prevent a decrease in withstand voltage compared to a case in which the boundary trenches 60 is not present. Therefore, this embodiment can also improve current-carrying capacity while preventing a decrease in withstand voltage.

The width of the diode region 30, where no trench gate structure is formed, is wider than the width of the boundary region 50, for example. The width of the diode region 30 is larger than the thickness of the semiconductor substrate, for example.

In the plurality of boundary trenches 60, it is preferable that one or more of the following conditions be met.
(1) Of the plurality of boundary trenches 60, the trench closest to the diode region 30 is shallower than the trench closest to the IGBT region 10.
(2) Of the plurality of boundary trenches 60, the trench closest to the diode region 30 is narrower than the trench closest to the IGBT region 10.
(3) The plurality of boundary trenches 60 have a different pitch from that of the IGBT trenches 20.

In the boundary region 50 shown in FIGS. 5 and 6, of the plurality of boundary trenches 60, the trench closest to the diode region 30 is shallower than the trench closest to the IGBT region 10. In this case, each of the plurality of boundary trenches 60 may have a depth that decreases from the IGBT region 10 toward the diode region 30. This makes it possible to gradually relax the electric field at the lower part of the trench. Therefore, the withstand voltage can be improved. Note that the plurality of boundary trenches 60 may include trenches of the same depth.

As shown in FIG. 6, of the plurality of boundary trenches 60, the trench closest to the diode region 30 may be narrower than the trench closest to the IGBT region 10. Each of the plurality of boundary trenches 60 may have a width that decreases from the IGBT region 10 toward the diode region 30. Note that the plurality of boundary trenches 60 may include trenches of the same narrowness.

Furthermore, as shown in FIG. 6, among the plurality of boundary trenches 60, a trench may be narrower as it is shallower. When both conditions (1) and (2) are met, trenches of different depths can be formed by a single etching process. This makes it possible to improve productivity.

The plurality of boundary trenches 60 may also have a different pitch from that of the plurality of IGBT trenches 20. In this case, the plurality of boundary trenches 60 may have a portion where the pitch is longer or shorter than that of the IGBT trenches 20. The pitch of the plurality of boundary trenches 60 does not have to be constant. As shown in FIG. 6, the pitch may change due to change of the width of the boundary trench 60, or the pitch may be variable while the width of the boundary trench 60 is constant.

In this embodiment, a cathode layer 39 is provided on the back surface side of the boundary region 50 in the semiconductor substrate. This makes it possible to improve the electron injection efficiency and further reduce VF. In the example of FIG. 6, the entire bottom surface of the semiconductor substrate in the boundary region 50 is formed by the cathode layer 39. The cathode layer 39 only needs to be provided on at least a part of the back surface side of the boundary region 50.

In the following embodiments, description is to be made with an example in which a structure in which no diode trench 40 is formed in the diode region 30. However, the following embodiments can be combined with the first or the second embodiment. For example, the diode region 30 of this embodiment can be replaced with the diode region 30 of the first or the second embodiment.

### Fourth Embodiment

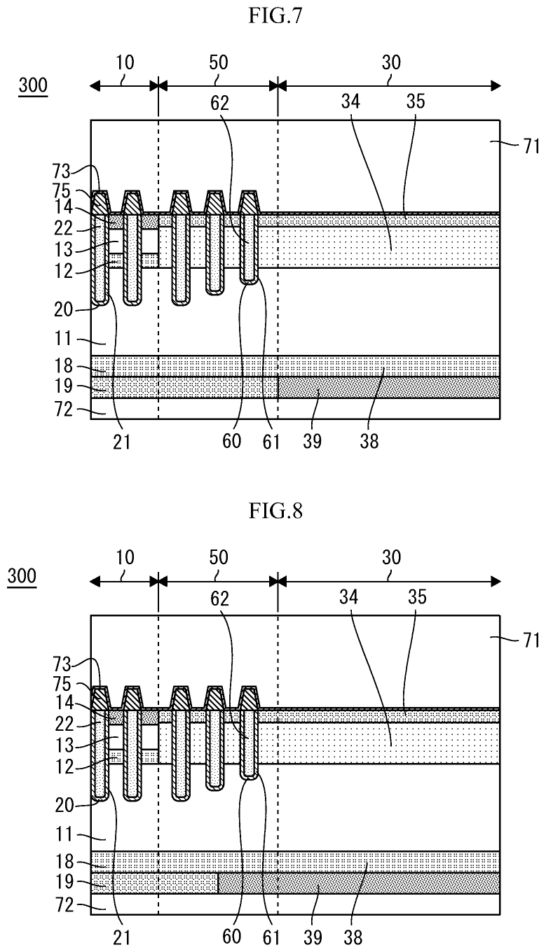

FIG. 7 is a cross-sectional view of a semiconductor device 300 according to a fourth embodiment. In this embodiment, a collector layer 19 is provided on the back surface side of the boundary region 50 of the semiconductor substrate. In the example of FIG. 7, the entire bottom surface of the semiconductor substrate in the boundary region 50 is formed by the collector layer 19. The collector layer 19 only needs to be provided on at least a part of the back surface side of the boundary region 50. In this embodiment, the inflow of holes from the base layer 13 of the IGBT region 10 can be prevented, thereby reducing recovery loss.

### Fifth Embodiment

FIG. 8 is a cross-sectional view of a semiconductor device 300 according to a fifth embodiment. The cathode layer 39 and the collector layer 19 may be provided on the back surface side of the semiconductor substrate in the boundary region. In other words, the boundary between the cathode layer 39 and the collector layer 19 may be present in the boundary region 50.

### Sixth Embodiment

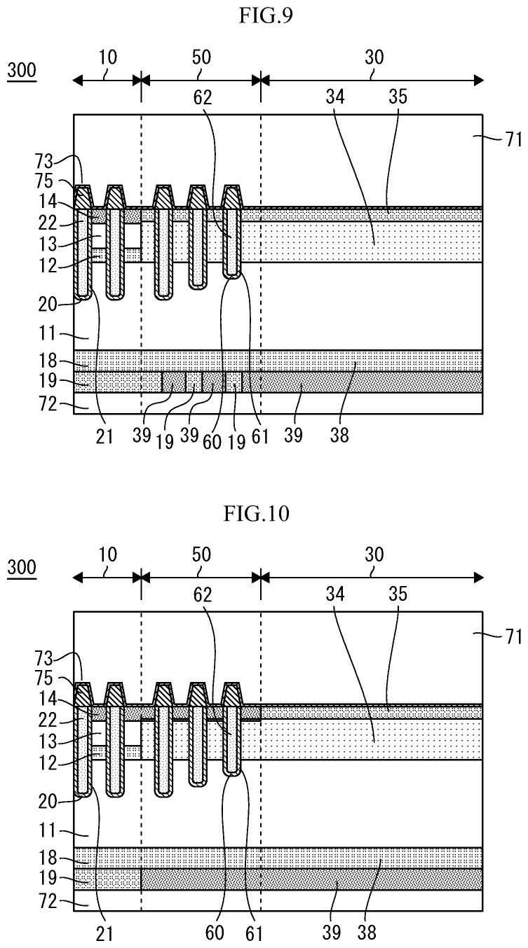

FIG. 9 is a cross-sectional view of a semiconductor device 300 according to a sixth embodiment. The cathode layers 39 and collector layers 19 may be provided alternately on the back surface side of the semiconductor substrate in the boundary region 50. In other words, the cathode layers 39 and the collector layers 19 may be positioned discretely.

### Seventh Embodiment

FIG. 10 is a cross-sectional view of a semiconductor device 300 according to a seventh embodiment. In the third embodiment, the emitter layer 14 is not provided in the boundary region 50. In contrast, in this embodiment, the uppermost surface of the semiconductor substrate in the boundary region 50 is formed by the emitter layer 14. In addition, the plurality of boundary trenches 60 is in contact with the emitter layer 14. Extending the emitter layer 14 into the boundary region 50 can stabilize the shape of the emitter layer 14 in the IGBT region 10. Therefore, the stability of the IGBT characteristics can be improved.

Note that it is sufficient that at least one of the plurality of boundary trenches 60 is in contact with the emitter layer 14. In other words, the emitter layer 14 does not need to extend to the boundary between the diode region 30 and the boundary region 50.

### Eighth Embodiment

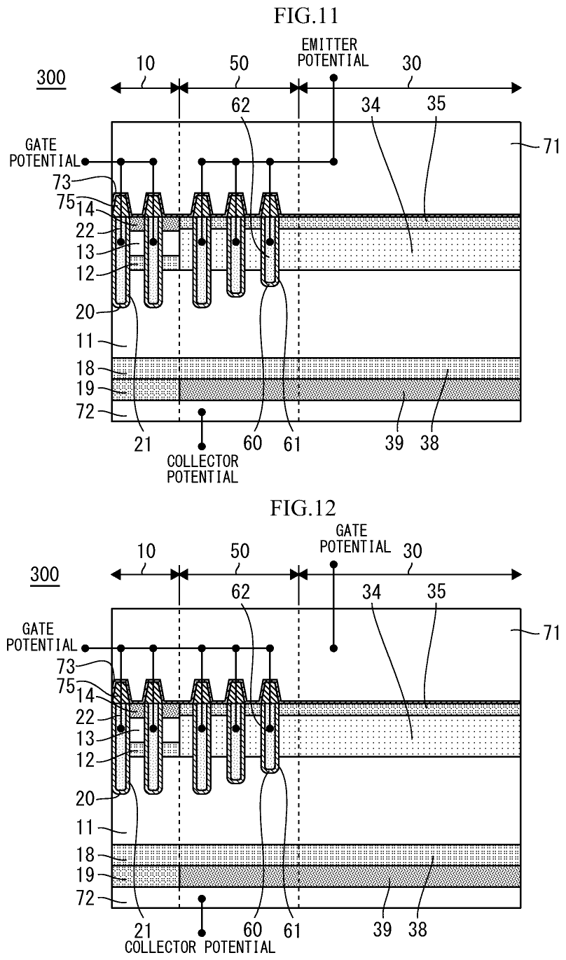

FIG. 11 is a cross-sectional view of a semiconductor device 300 according to an eighth embodiment. In this embodiment, the boundary gate electrodes 62 are electrically connected to the front surface electrode 71. In FIG. 11, all of the boundary gate electrodes 62 are at emitter potential, but it is sufficient that a boundary gate electrode 62, provided inside at least one of the plurality of boundary trenches 60, is at emitter potential. In this embodiment, the gate capacitance can be reduced and the switching speed can be increased. This makes it possible to reduce switching loss.

Note that in this embodiment, the insulating interlayer film 75 on the boundary gate electrode 62 may be omitted. When an insulating interlayer film 75 is present on the boundary gate electrodes 62, the boundary gate electrodes 62 and the front surface electrode 71 are connected at a location other than the cross section in FIG. 11. When the insulating interlayer film 75 is not present on the boundary gate electrodes 62, the boundary gate electrodes 62 and the front surface electrode 71 can be connected in the cross section in FIG. 11.

### Nineth Embodiment

FIG. 12 is a cross-sectional view of a semiconductor device 300 according to a nineth embodiment. In this embodiment, the boundary gate electrodes 62 are electrically connected to the IGBT gate electrodes 22. In FIG. 12, all of the boundary gate electrodes 62 are at gate potential and are insulated from the emitter electrode. The configuration is not limited to this, and it is sufficient that a boundary gate electrode 62, provided inside at least one of the plurality of boundary trenches 60, is at gate potential. In this embodiment, an inversion layer can be formed near the boundary trenches 60 when a gate voltage is applied, thereby reducing recovery loss.

### Tenth Embodiment

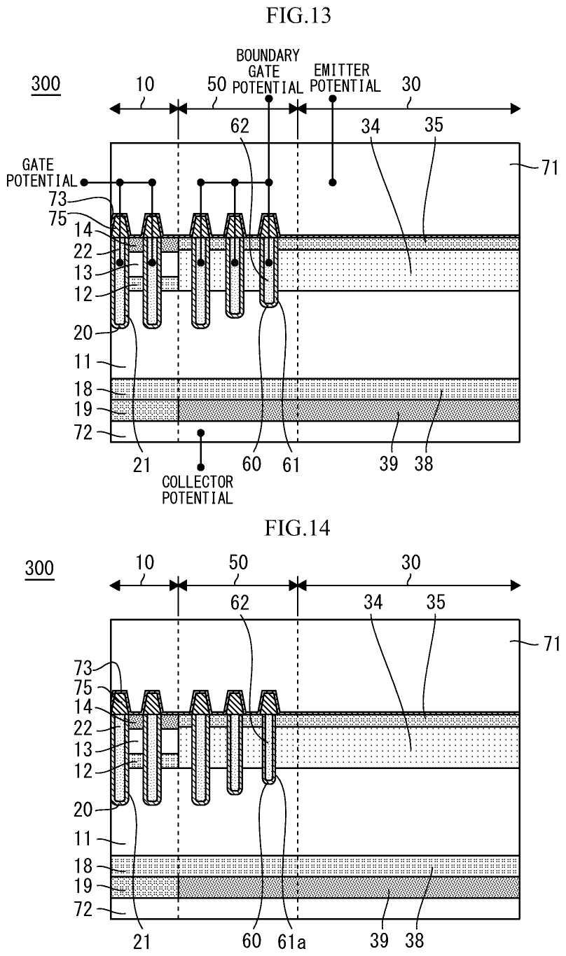

FIG. 13 is a cross-sectional view of a semiconductor device 300 according to a tenth embodiment. The boundary gate electrodes 62 may be electrically independent from the front surface electrode 71 and the IGBT gate electrodes 22. In other words, the boundary gate electrodes 62 may be insulated from the IGBT gate electrodes 22 and the front surface electrode 71, and may have an independent boundary gate potential. In the example of FIG. 13, all of the boundary gate electrodes 62 are at boundary gate potential, but it is sufficient that a boundary gate electrode 62, provided inside at least one of the plurality of boundary trenches 60, is at boundary gate potential. In this embodiment, a voltage can be applied to the boundary gate electrodes 62 at any timing. For example, when a negative bias is applied to the boundary gate electrodes 62, the recovery loss can be reduced by hole extraction.

### Eleventh Embodiment

FIG. 14 is a cross-sectional view of a semiconductor device 300 according to an eleventh embodiment. In this embodiment, the boundary gate insulating film 61a is thinner than the IGBT gate insulating film 21. In FIG. 14, all of the boundary gate insulating films 61a are formed thin, but it is sufficient that a boundary gate insulating film 61a, formed on the inner wall of at least one of the plurality of boundary trenches 60, is formed thin. In this embodiment, the field plate effect is improved, thereby making it possible to improve the withstand voltage.

### Twelfth Embodiment

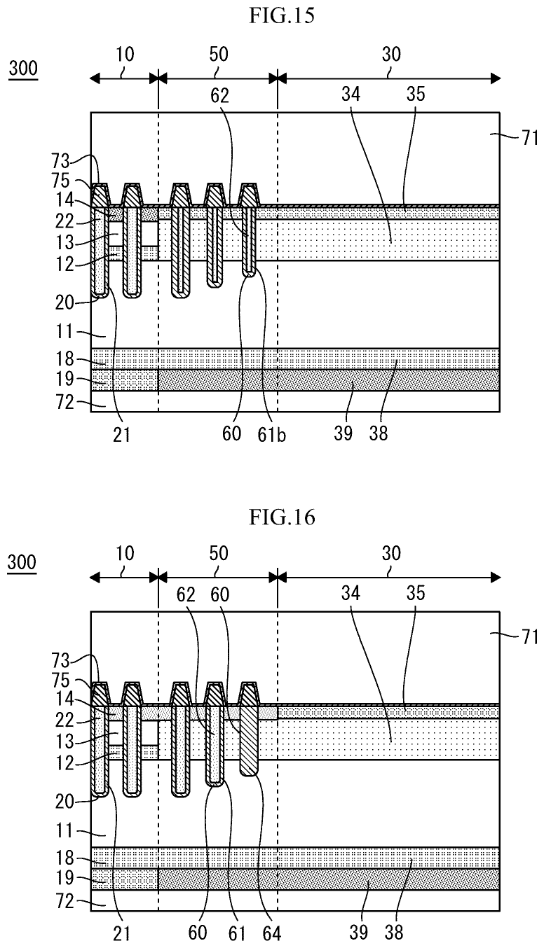

FIG. 15 is a cross-sectional view of a semiconductor device 300 according to a twelfth embodiment. In this embodiment, the boundary gate insulating film 61b is thicker than the IGBT gate insulating film 21. Note that in FIG. 15, all of the boundary gate insulating films 61b are formed thick, but it is sufficient that a boundary gate insulating film 61b, formed on the inner wall of at least one of the plurality of boundary trenches 60, is formed thick. In this embodiment, the boundary gate electrode 62 can be protected, thereby improving reliability of the boundary gate electrode 62.

### Thirteenth Embodiment

FIG. 16 is a cross-sectional view of a semiconductor device 300 according to a thirteenth embodiment. In this embodiment, at least one of the plurality of boundary trenches 60 is filled with a dielectric 64. Note that all of the boundary trenches 60 may be filled with the dielectrics 64. In this embodiment, breakdown due to high electric fields can be prevented, improving the reliability of the boundary gate electrodes 62.

### Fourteenth Embodiment

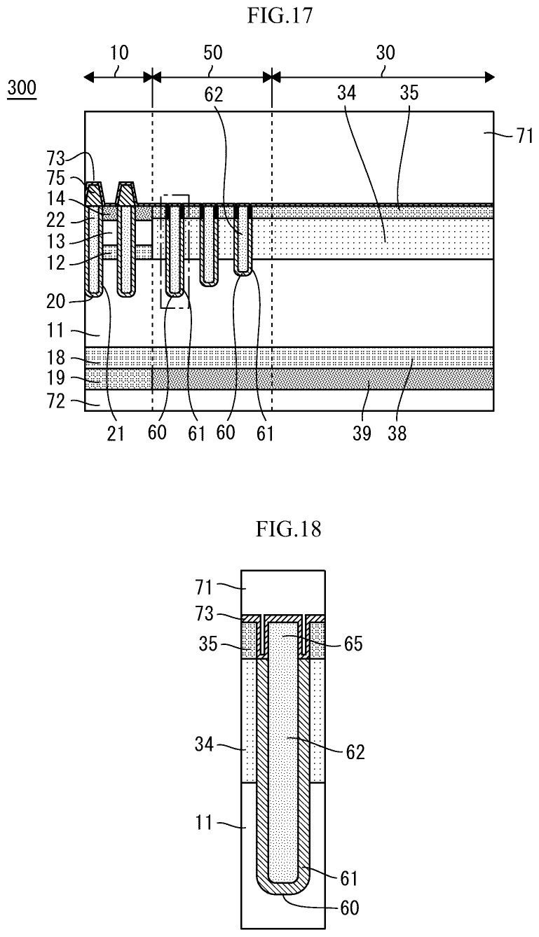

FIG. 17 is a cross-sectional view of a semiconductor device 300 according to a fourteenth embodiment. FIG. 18 is an enlarged view of FIG. 17. The boundary gate electrodes 62 of this embodiment each have a protrusion 65 protruding upward relative to the boundary gate insulating film 61. The front surface electrode 71 is in contact with the upper surface and side surface of the protrusion 65. That is, the front surface electrode 71 extends into each recess at the side of the polysilicon. Such a structure of the front surface electrode 71 is also called a recess side contact electrode. This makes it possible to improve the hole extraction efficiency and reduce recovery loss.

The recess side contact electrode is formed, for example, by over-etching, which hollows out the gate oxide film, during contact formation. Note that the barrier metal 73 shown in FIG. 18 may be omitted. In addition, in FIG. 17, the recess side contact electrode is formed on all of the boundary gate electrodes 62, but it is sufficient that the recess side contact electrode is formed on at least one of the boundary gate electrodes 62.

### Fifteenth Embodiment

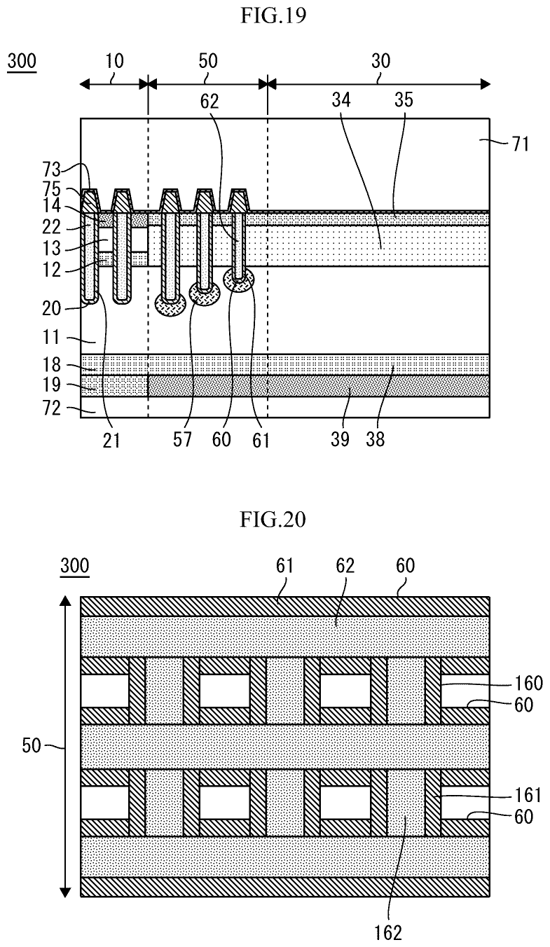

FIG. 19 is a cross-sectional view of a semiconductor device 300 according to a fifteenth embodiment. In this embodiment, an electric field relaxation layer 57 of P-type is provided under each of the plurality of boundary trenches 60 in the drift layer 11. In FIG. 19, an electric field relaxation layer 57 is provided under each of the boundary trenches 60, but it is sufficient that an electric field relaxation layer 57 is provided under at least one boundary trench 60. In this embodiment, the electric field under the trenches can be relaxed, making it possible to improve the withstand voltage.

### Sixteenth Embodiment

FIG. 20 is a plan view of a semiconductor device 300 according to a sixteenth embodiment. In this embodiment, ladder trenches 160 are formed on the upper surface of the boundary region 50 so as to connect the plurality of boundary trenches 60 in plan view. Each ladder trench 160 extends in a direction intersecting the longitudinal direction of the boundary trenches 60 in plan view. Ladder gate electrodes 162 are each provided inside the ladder trenches 160, via a ladder gate insulating films 161. This embodiment makes it possible to relax the electric field, and improve the withstand voltage.

In FIG. 20, a pair of boundary trenches 60 are connected by a plurality of ladder trenches 160. The configuration is not limited to this, and a pair of boundary trenches 60 only needs to be connected by one or more ladder trenches 160. The ladder trench 160 may be provided between every adjacent boundary trenches 60. The plurality of boundary trenches 60 may include a pair of boundary trenches 60 with no ladder trench 160 provided therebetween.

### Seventeenth Embodiment

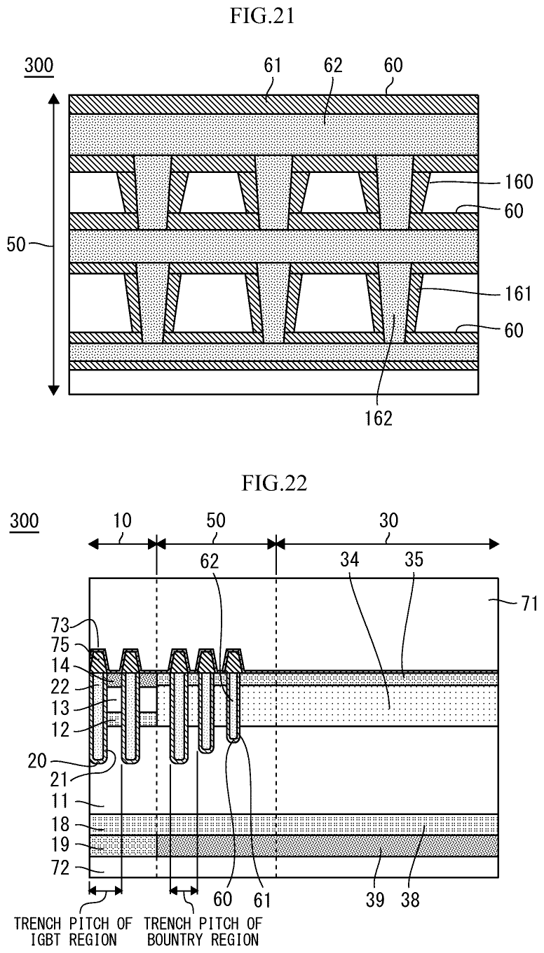

FIG. 21 is a plan view of a semiconductor device 300 according to a seventeenth embodiment. The ladder trench 160 may vary in width depending on the thickness of the boundary trench 60 to which it is connected. In the example of FIG. 21, the plurality of boundary trenches 60 include first trenches and second trenches each of which is adjacent to a corresponding one of first trenches and narrower than the first trench. Each ladder trench 160 connecting the first trench and second trench is narrower on the second trench side than on the first trench side. This embodiment also makes it possible to relax the electric field, and improve the withstand voltage.

### Eighteenth Embodiment

FIG. 22 is a cross-sectional view of a semiconductor device 300 according to an eighteenth embodiment. In this embodiment, the boundary trenches 60 are positioned at a different pitch from that of the IGBT trenches 20. The withstand voltage of the boundary region 50 can be controlled by the pitch of the boundary trench 60. In FIG. 22, the pitch of the boundary trenches 60 is shorter than the pitch of the IGBT trenches 20. This makes it possible to improve the withstand voltage. Note that the pitch of the boundary trenches 60 may be shorter than that of the IGBT trenches 20 in a part of the boundary region 50.

### Nineteenth Embodiment

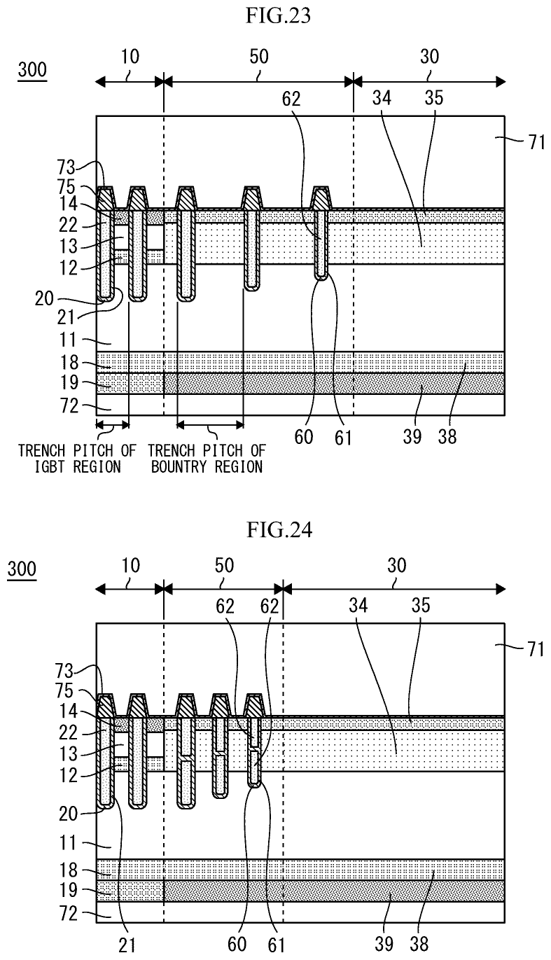

FIG. 23 is a cross-sectional view of a semiconductor device 300 according to a nineteenth embodiment. In this embodiment, the pitch of the boundary trenches 60 is longer than the pitch of the IGBT trenches 20. This decreases the withstand voltage but makes it possible to improve the current-carrying capacity. Note that the pitch of the boundary trenches 60 may be longer than that of the IGBT trenches 20 in a part of the boundary region 50. In the eighteenth and nineteenth embodiments, the degree of freedom in withstand voltage design can be improved.

### Twentieth Embodiment

FIG. 24 is a cross-sectional view of a semiconductor device 300 according to a twentieth embodiment. In this embodiment, each boundary gate electrode 62 is divided into upper and lower parts inside the corresponding boundary trench 60. The boundary gate electrode 62, divided into the upper and lower parts, is separated by a boundary gate insulating film 61. Note that in FIG. 24, the boundary gate electrodes 62 are divided into upper and lower parts in all of the boundary trenches 60. The configuration is not limited to this, and it is sufficient that a boundary gate electrode 62, provided inside at least one of the plurality of boundary trenches 60, is divided into upper and lower parts. The boundary gate electrode 62 may be divided into two or more parts. According to this embodiment, the capacity of the boundary region 50 can be adjusted, and design flexibility is improved regarding loss.

### Twenty-First Embodiment

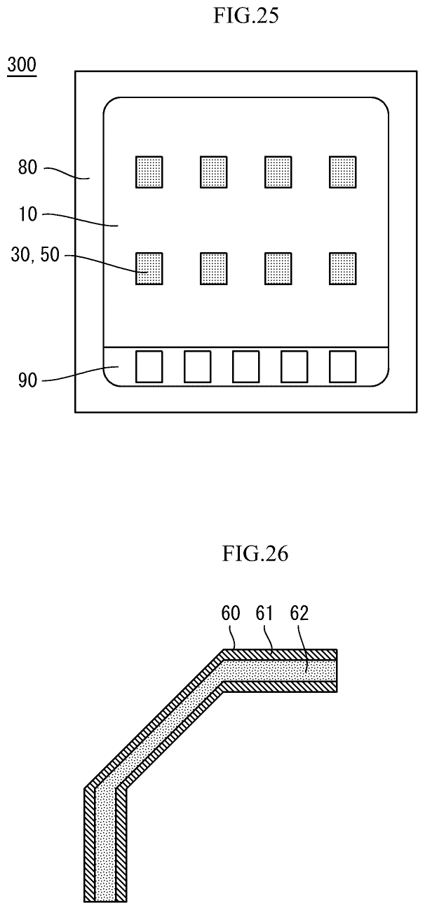

FIG. 25 is a plan view of a semiconductor device 300 according to a twenty-first embodiment. In this embodiment, the IGBT region 10 is provided so as to surround the diode regions 30 and the boundary regions 50 in plan view. Each of the boundary regions 50 is provided so as to surround a corresponding one of the diode regions 30 in plan view. In this case, the boundary trench 60 is provided along the diode region 30, for example.

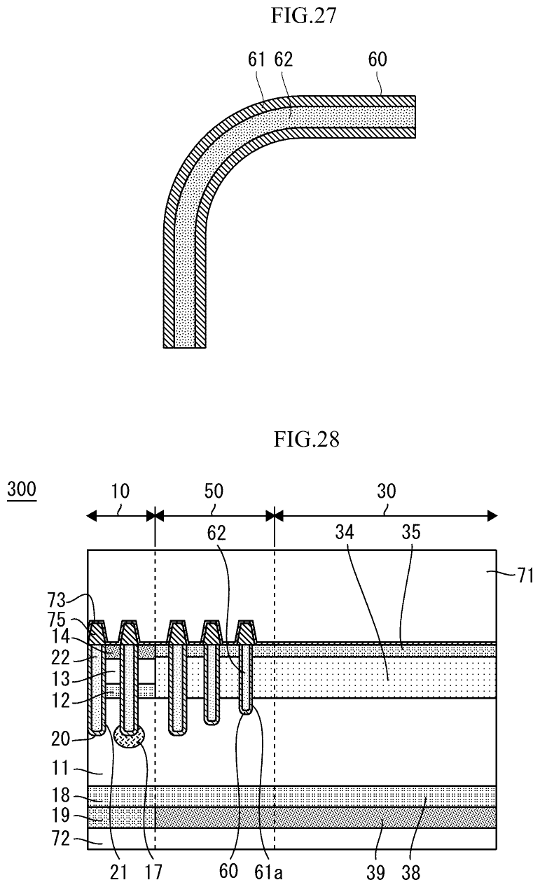

FIG. 26 is an enlarged view of FIG. 25. FIG. 27 is a plan view of a semiconductor device 300 according to a modification of the twenty-first embodiment. In plan view, corner portions of the boundary trench 60 along the diode region 30 are each formed with an obtuse angle or a curved surface. FIG. 26 shows an example in which a corner portion of the boundary trench 60 is formed with an obtuse angle. FIG. 27 shows an example in which a corner portion of the boundary trench 60 is formed with a curved surface. In this embodiment, it is possible to relax the electric field at the corners of the trench where the electric field is likely to concentrate, thereby improving the withstand voltage.

In this embodiment, a diode region 30 is surrounded by a plurality of boundary trenches 60. For example, when three boundary trenches 60 are present, the diode region 30 is surrounded by three boundary trenches 60. In other words, the plurality of boundary trenches 60 may be provided concentrically around the diode region 30. Note that it is sufficient that the corner portions of at least one of the plurality of boundary trenches 60 are each formed with an obtuse angle or a curved surface. In addition, each boundary trench 60 may be annular in plan view, or may be divided in the circumferential direction of the boundary region 50.

### Twenty-Second Embodiment

FIG. 28 is a cross-sectional view of a semiconductor device 300 according to a twenty-second embodiment. In this embodiment, in the drift layer 11, an electric field relaxation layer 17 of P-type is provided under the IGBT trench 20 closest to the diode region 30 in the IGBT region 10. Note that the electric field relaxation layer 17 may be provided under another IGBT trench 20 in addition to under the IGBT trench 20 closest to the diode region 30. This embodiment makes it possible to relax the electric field, and improve the withstand voltage.

The carrier accumulation layer 12 is provided deeper than the base layer 13, on the upper surface side of the drift layer 11 in the IGBT region 10. The carrier accumulation layer 12 is not provided in the diode region 30. This makes it possible to relax the electric field, and improve the withstand voltage.

Specifically, the side surface of the carrier accumulation layer 12 closest to the diode region 30 is in contact with the anode layer 34 in the boundary region 50. The configuration is not limited to this, and the side surface of the carrier accumulation layer 12 closest to the diode region 30 may be in contact with one of the plurality of boundary trenches 60. The carrier accumulation layer 12 extends, at its longest, to a position where it is in contact with the boundary trench 60 closest to the diode region 30. In this way, providing no carrier accumulation layer 12 in the diode region 30 makes it possible to improve the withstand voltage.

### Twenty-Third Embodiment

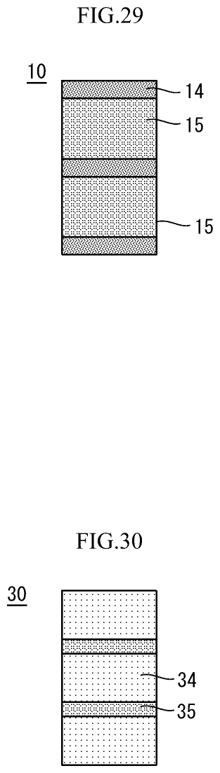

FIG. 29 is a plan view of an IGBT region 10 according to a twenty-third embodiment. FIG. 30 is a plan view of a diode region 30 according to the twenty-third embodiment. The emitter layers 14 and the IGBT contact layers 15 having a higher concentration than the emitter layers 14 are formed on the uppermost surface of the IGBT region 10. The anode layers 34 and the diode contact layers 35 having a higher concentration than the anode layers 34 are formed on the uppermost surface of the diode region 30. In plan view, the ratio of the area of the diode contact layer 35 to the area of the diode region 30 is smaller than the ratio of the area of the IGBT contact layer 15 to the area of the IGBT region 10. In other words, the following expression holds.

$$\frac{IGBT P + Contact Area {S}_{IGBT p +}}{IGBT Cell Area {S}_{IGBT cell}} > \frac{Diode P + Contact Area {S}_{Diode p +}}{Diode Cell Area {S}_{Diode cell}} \qquad [ Math . 1 ]$$

This makes it possible to reduce the hole injection efficiency and reduce the recovery loss.

### Twenty-Fourth Embodiment

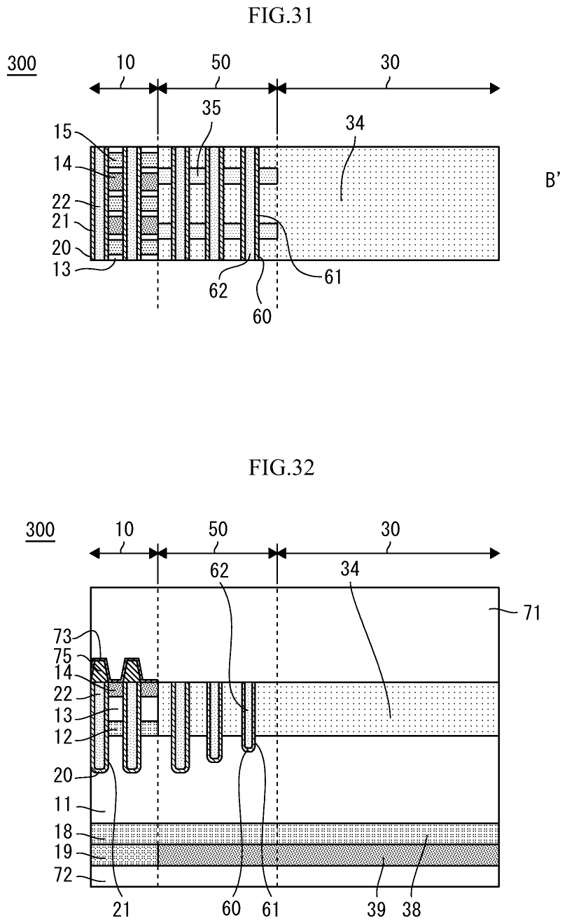

FIG. 31 is a plan view of a semiconductor device 300 according to a twenty-fourth embodiment. In this embodiment, the maximum concentration of the second conductivity type layer at the uppermost surface of the diode region 30 is lower than the maximum concentration of the second conductivity type layer at the uppermost surface of the IGBT region 10. In the example of FIG. 31, no diode contact layer 35 is formed in the diode region 30. In this case, the concentration of the anode layer 34 only needs to be lower than the concentration of the IGBT contact layer 15. When a diode contact layer 35 is present in the diode region 30, the concentration of the diode contact layer 35 only needs to be lower than the concentration of the IGBT contact layer 15. This makes it possible to reduce the hole injection efficiency and reduce the recovery loss.

### Twenty-Fifth Embodiment

FIG. 32 is a cross-sectional view of a semiconductor device 300 according to a twenty-fifth embodiment. In this embodiment, the front surface electrode 71 is made of a metal containing Al or Ni. The upper surface of the diode region 30 is in direct contact with the front surface electrode 71. In other words, the upper surface of the semiconductor substrate in the diode region 30 is in contact with the front surface electrode 71 without the barrier metal 73 and insulating interlayer film 75 interposed therebetween. This makes it possible to improve ohmic contact and reduce VF. Note that, as shown in FIG. 32, the diode contact layer 35 does not have to be provided in the diode region 30.

### Twenty-Sixth Embodiment

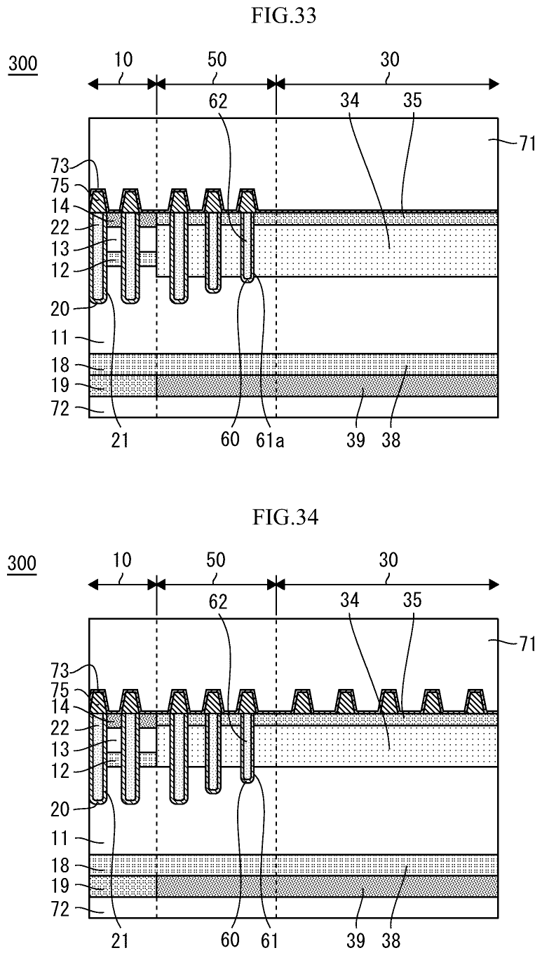

FIG. 33 is a cross-sectional view of a semiconductor device 300 according to a twenty-sixth embodiment. In this embodiment, the anode layer 34 is provided in the boundary region 50 and the diode region 30 to a position deeper than the carrier accumulation layer 12 in the IGBT region 10. This makes it possible to relax the electric field, and improve the withstand voltage.

### Twenty-Seventh Embodiment

FIG. 34 is a cross-sectional view of a semiconductor device 300 according to a twenty-seventh embodiment. In this embodiment, a plurality of contact holes for causing the upper surface of the diode region 30 to be in contact with the front surface electrode 71 are positioned on the upper surface of the diode region 30. Specifically, a plurality of insulating interlayer films 75 are positioned on the upper surface of the diode region 30. As a result, the regions between the plurality of insulating interlayer films 75 become contact holes. In this manner, a plurality of contact holes can be discretely positioned in one diode region 30. This makes it possible to improve the carrier accumulation effect and reduce VF.

The configuration is not limited to this, and as shown in FIG. 6, only one contact hole for causing the upper surface of the diode region 30 to be in contact with the front surface electrode 71 may be formed on the upper surface of one diode region 30. In other words, the contact hole in the diode region 30 does not have to be separated by the insulating interlayer film 75. This makes it possible to reduce contact resistance and reduce VF.

In the above embodiments, the IGBT regions 10 and the diode regions 30 may be provided at different intervals or may be positioned in a staggered pattern. The diode contact layer 35 does not have to be provided in the boundary region 50 and the diode region 30. The diode contact layer 35 may be positioned in a staggered pattern. The electric field relaxation layers of P-type may be provided under all or one or more of the diode trenches 40. Each electric field relaxation layer may be in contact with the trench or may be spaced apart from the trench. The front surface electrode 71 and the back surface electrode 72 may be deposited through plating.

### Twenty-Eighth Embodiment

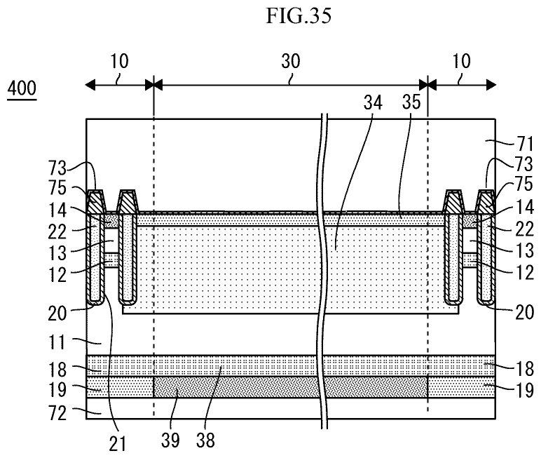

FIG. 35 is a cross-sectional view of a semiconductor device 400 according to a twenty-eighth embodiment. In this embodiment, the IGBT regions 10 and the diode region 30 are provided adjacently to each other in the semiconductor substrate. One or more IGBT trenches 20 are formed on the upper surface of each IGBT region 10. No trench gate structure is formed on the upper surface of the diode region 30. The anode layer 34 in the diode region 30 is provided to a position deeper than the IGBT trench 20. The anode layer 34 is provided so as to cover the lower end of the trench provided closest to the diode region 30 among the IGBT trenches 20. The other structures are the same as those in the first embodiment.

In this embodiment, the current-carrying capacity can be improved because no trench gate structure is formed in the diode region 30. In addition, the anode layer 34 covers the lower part of the trench at the end of each IGBT region 10 where the electric field is likely to concentrate. This makes it possible to prevent a decrease in withstand voltage.

Note that the diode contact layer 35 may be provided over the entire surface of the diode region 30, may be provided in a part of the diode region 30, or may be absent. The concentration of the anode layer 34 may be the same as, higher than, or lower than the concentration of the base layer 13.

Meanwhile, technical features explained in each embodiment may be appropriately combined to use.

Hereinafter, various aspects of the present disclosure will be collectively described as appendixes.

(Appendix 1)

A semiconductor device comprising:
a semiconductor substrate having an IGBT region and a diode region, the IGBT region having an upper surface on which one or more IGBT trenches are formed, the diode region having an upper surface on which one or more diode trenches are formed;
a front surface electrode provided on an upper surface of the semiconductor substrate;
a back surface electrode provided on a back surface of the semiconductor substrate;
IGBT gate electrodes provided inside the respective IGBT trenches; and
diode gate electrodes provided inside the respective diode trenches, wherein
the diode trenches are deeper than an anode layer of the diode region, and
(WDT×N)/WD≤0.13 is satisfied, where WD is a width of the diode region in a direction in which the IGBT region and the diode region are aligned, WDT is a width of one of the diode trenches, and N is the number of the diode trenches.

### (Appendix 2)

The semiconductor device according to appendix 1, wherein
the semiconductor substrate has a boundary region between the IGBT region and the diode region,
a plurality of boundary trenches are formed on an upper surface of the boundary region, and
the plurality of boundary trenches and the IGBT trenches differ in at least one of trench pitch, depth, and width.

### (Appendix 3)

A semiconductor device comprising:
a semiconductor substrate having an IGBT region, a diode region, and a boundary region between the IGBT region and the diode region, the IGBT region having an upper surface on which one or more IGBT trenches are formed, the diode region having an upper surface on which no trench gate structure is formed;
a front surface electrode provided on an upper surface of the semiconductor substrate;
a back surface electrode provided on a back surface of the semiconductor substrate; and
IGBT gate electrodes provided inside the respective IGBT trenches, wherein
a plurality of boundary trenches are formed on an upper surface of the boundary region, and
the plurality of boundary trenches satisfies one or more of the following:
   a trench closest to the diode region is shallower than a trench closest to the IGBT region;
   a trench closest to the diode region is narrower than a trench closest to the IGBT region; and
   a pitch of the boundary trenches is different from a pitch of the IGBT trenches.

### (Appendix 4)

The semiconductor device according to appendix 2 or 3, wherein among the plurality of boundary trenches, a trench closest to the diode region is shallower than a trench closest to the IGBT region.

### (Appendix 5)

The semiconductor device according to appendix 4, wherein each of the plurality of boundary trenches has a depth that decreases from the IGBT region toward the diode region.

### (Appendix 6)

The semiconductor device according to appendix 4, wherein among the plurality of boundary trenches, a trench is narrower as the trench is shallower.

### (Appendix 7)

The semiconductor device according to any one of appendixes 2 to 6, wherein among the plurality of boundary trenches, a trench closest to the diode region is narrower than a trench closest to the IGBT region.

### (Appendix 8)

The semiconductor device according to appendix 7, wherein each of the plurality of boundary trenches has a width that decreases from the IGBT region toward the diode region.

### (Appendix 9)

The semiconductor device according to any one of appendixes 2 to 8, wherein the plurality of boundary trenches have a pitch different from a pitch of the IGBT trenches.

### (Appendix 10)

The semiconductor device according to any one of appendixes 2 to 9, wherein a cathode layer is provided on the back surface side of the boundary region of the semiconductor substrate.

### (Appendix 11)

The semiconductor device according to any one of appendixes 2 to 10, wherein a collector layer is provided on the back surface side of the boundary region of the semiconductor substrate.

### (Appendix 12)

The semiconductor device according to any one of appendixes 2 to 10, wherein a cathode layer and a collector layer are provided on the back surface side of the boundary region of the semiconductor substrate.

### (Appendix 13)

The semiconductor device according to any one of appendixes 2 to 10, wherein cathode layers and collector layers are alternately provided on the back surface side of the boundary region of the semiconductor substrate.

### (Appendix 14)

The semiconductor device according to any one of appendixes 2 to 13, wherein at least one of the plurality of boundary trenches is in contact with an emitter layer.

### (Appendix 15)

The semiconductor device according to any one of appendixes 2 to 14, further comprising a boundary gate electrode provided inside at least one of the plurality of boundary trenches, wherein
the boundary gate electrode is electrically connected to the front surface electrode.

### (Appendix 16)

The semiconductor device according to any one of appendixes 2 to 15, further comprising a boundary gate electrode provided inside at least one of the plurality of boundary trenches, wherein
the boundary gate electrode is electrically connected to the IGBT gate electrodes.

### (Appendix 17)

The semiconductor device according to any one of appendixes 2 to 16, further comprising a boundary gate electrode provided inside at least one of the plurality of boundary trenches, wherein
the boundary gate electrode is electrically independent from the front surface electrode and the IGBT gate electrodes.

### (Appendix 18)

The semiconductor device according to any one of appendixes 2 to 17, further comprising:
IGBT gate insulating films each formed on an inner wall of a corresponding one of the IGBT trenches;
a boundary gate insulating film formed on an inner wall of at least one of the plurality of boundary trenches; and
a boundary gate electrode provided inside at least one of the plurality of boundary trenches via the boundary gate insulating film, wherein
the boundary gate insulating film is thinner than the IGBT gate insulating films.

### (Appendix 19)

The semiconductor device according to any one of appendixes 2 to 17, further comprising:
IGBT gate insulating films each formed on an inner wall of a corresponding one of the IGBT trenches;
a boundary gate insulating film formed on an inner wall of at least one of the plurality of boundary trenches; and
a boundary gate electrode provided inside at least one of the plurality of boundary trenches via the boundary gate insulating film, wherein
the boundary gate insulating film is thicker than the IGBT gate insulating films.

### (Appendix 20)

The semiconductor device according to any one of appendixes 2 to 19, wherein at least one of the plurality of boundary trenches is filled with a dielectric.

### (Appendix 21)

The semiconductor device according to any one of appendixes 2 to 20, further comprising:
a boundary gate insulating film formed on an inner wall of at least one of the plurality of boundary trenches; and
a boundary gate electrode provided inside at least one of the plurality of boundary trenches via the boundary gate insulating film, wherein
the boundary gate electrode has a protrusion that protrudes upward relative to the boundary gate insulating film, and
the front surface electrode is in contact with an upper surface and a side surface of the protrusion.

### (Appendix 22)

The semiconductor device according to any one of appendixes 2 to 21, further comprising:
a drift layer of a first conductivity type provided in the semiconductor substrate; and
an electric field relaxation layer of a second conductivity type provided in the drift layer under at least one of the plurality of boundary trenches.

### (Appendix 23)

The semiconductor device according to any one of appendixes 2 to 22, wherein a ladder trench is formed on an upper surface of the boundary region so as to connect the plurality of boundary trenches in plan view.

### (Appendix 24)

The semiconductor device according to appendix 23, wherein
the plurality of boundary trenches include a first trench and a second trench adjacent to the first trench and narrower than the first trench, and
the ladder trench connecting the first trench and the second trench is narrower on a side of the second trench than on a side of the first trench.

### (Appendix 25)

The semiconductor device according to any one of appendixes 2 to 24, further comprising a boundary gate electrode provided inside at least one of the plurality of boundary trenches, wherein
the boundary gate electrode is divided into upper and lower parts inside a boundary trench corresponding to the boundary gate electrode.

### (Appendix 26)

The semiconductor device according to any one of appendixes 2 to 25, wherein
the boundary region is provided so as to surround the diode region in plan view, and
in plan view, at least one of the plurality of boundary trenches has corner portions, along the diode region, each formed with an obtuse angle or a curved surface.

### (Appendix 27)

The semiconductor device according to any one of appendixes 2 to 21, further comprising:
a drift layer of a first conductivity type provided in the semiconductor substrate; and
an electric field relaxation layer of a second conductivity type provided in the drift layer, under the IGBT trench closest to the diode region in the IGBT region.

### (Appendix 28)

The semiconductor device according to any one of appendixes 2 to 21, further comprising:
a drift layer of a first conductivity type provided in the semiconductor substrate;
a base layer of a second conductivity type provided on an upper surface side of the drift layer in the IGBT region; and
a carrier accumulation layer of the first conductivity type that is provided deeper than the base layer on an upper surface side of the drift layer in the IGBT region and that is not provided in the diode region.

### (Appendix 29)

The semiconductor device according to appendix 28, wherein a side surface of the carrier accumulation layer closest to the diode region is in contact with any of the plurality of boundary trenches or an anode layer.

### (Appendix 30)

The semiconductor device according to appendix 28 or 29, wherein an anode layer is provided to a position deeper than the carrier accumulation layer.

### (Appendix 31)

The semiconductor device according to any one of appendixes 2 to 30, wherein
an emitter layer and an IGBT contact layer having a higher concentration than the emitter layer are formed on an uppermost surface of the IGBT region,
an anode layer and a diode contact layer having a higher concentration than the anode layer are formed on an uppermost surface of the diode region, and
in plan view, a ratio of an area of the diode contact layer to an area of the diode region is smaller than a ratio of an area of the IGBT contact layer to an area of the IGBT region.

### (Appendix 32)

The semiconductor device according to any one of appendixes 2 to 21, further comprising a drift layer of a first conductivity type provided in the semiconductor substrate, wherein
a maximum concentration of a layer of a second conductivity type on an uppermost surface of the diode region is lower than a maximum concentration of a layer of a second conductivity type on an uppermost surface of the IGBT region.

### (Appendix 33)

The semiconductor device according to any one of appendixes 2 to 32, wherein
the front surface electrode is made of a metal containing Al or Ni, and
an upper surface of the diode region is in direct contact with the front surface electrode.

### (Appendix 34)

The semiconductor device according to any one of appendixes 2 to 33, wherein a plurality of contact holes for causing an upper surface of the diode region to be in contact with the front surface electrode are positioned on the upper surface of the diode region.

### (Appendix 35)

The semiconductor device according to any one of appendixes 2 to 33, wherein only one contact hole for causing an upper surface of the diode region to be in contact with the front surface electrode is formed on the upper surface of the diode region.

### (Appendix 36)

A semiconductor device comprising:
a semiconductor substrate having an IGBT region and a diode region, the IGBT region having an upper surface on which one or more IGBT trenches are formed, the diode region having an upper surface on which no trench gate structure is formed;
a front surface electrode provided on an upper surface of the semiconductor substrate;
a back surface electrode provided on a back surface of the semiconductor substrate; and
IGBT gate electrodes provided inside the respective IGBT trenches, wherein
an anode layer of the diode region is provided so as to cover a lower end of a trench provided closest to the diode region among the IGBT trenches.

### (Appendix 37)

The semiconductor device according to any one of appendixes 1 to 36, wherein the semiconductor substrate is made with a wide band gap semiconductor.

### (Appendix 38)

The semiconductor device according to appendix 37, wherein the wide band gap semiconductor is silicon carbide, gallium-nitride-based material or diamond.

In the semiconductor device according to the first disclosure, the diode trench is left, thereby making it possible to prevent a decrease in the withstand voltage. Furthermore, (WDT×N)/WD≤0.13 is satisfied, thereby making it possible to reduce VF. Therefore, it is possible to improve the current-carrying capacity while preventing a decrease in the withstand voltage.

In the semiconductor device according to the second disclosure, a trench gate structure is not formed in the diode region, thereby making it possible to improve current-carrying capacity. In addition, the boundary trench is formed in the boundary region, thereby making it possible to prevent a decrease in withstand voltage.

In the semiconductor device according to the third disclosure, a trench gate structure is not formed in the diode region, thereby making it possible to improve current-carrying capacity. Furthermore, the anode layer covers the lower end of the trench provided closest to the diode region among the IGBT trenches, thereby making it possible to prevent a decrease in withstand voltage.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-047839, filed on Mar. 24, 2025 including specification, claims, drawings and summary, on which the Convention priority of the present application is based, are incorporated herein by reference in its entirety.

1. A semiconductor device comprising:
a semiconductor substrate having an IGBT region and a diode region, the IGBT region having an upper surface on which one or more IGBT trenches are formed, the diode region having an upper surface on which one or more diode trenches are formed;
a front surface electrode provided on an upper surface of the semiconductor substrate;
a back surface electrode provided on a back surface of the semiconductor substrate;
IGBT gate electrodes provided inside the respective IGBT trenches; and
diode gate electrodes provided inside the respective diode trenches, wherein
the diode trenches are deeper than an anode layer of the diode region, and
(WDT×N)/WD≤0.13 is satisfied, where WD is a width of the diode region in a direction in which the IGBT region and the diode region are aligned, WDT is a width of one of the diode trenches, and N is the number of the diode trenches.

2. The semiconductor device according to claim 1, wherein
the semiconductor substrate has a boundary region between the IGBT region and the diode region,
a plurality of boundary trenches are formed on an upper surface of the boundary region, and
the plurality of boundary trenches and the IGBT trenches differ in at least one of trench pitch, depth, and width.

3. A semiconductor device comprising:
a semiconductor substrate having an IGBT region, a diode region, and a boundary region between the IGBT region and the diode region, the IGBT region having an upper surface on which one or more IGBT trenches are formed, the diode region having an upper surface on which no trench gate structure is formed;
a front surface electrode provided on an upper surface of the semiconductor substrate;
a back surface electrode provided on a back surface of the semiconductor substrate; and
IGBT gate electrodes provided inside the respective IGBT trenches, wherein
a plurality of boundary trenches are formed on an upper surface of the boundary region, and
the plurality of boundary trenches satisfies one or more of the following:
a trench closest to the diode region is shallower than a trench closest to the IGBT region;
a trench closest to the diode region is narrower than a trench closest to the IGBT region; and
a pitch of the boundary trenches is different from a pitch of the IGBT trenches.

4. The semiconductor device according to claim 3, wherein among the plurality of boundary trenches, a trench closest to the diode region is shallower than a trench closest to the IGBT region.

5. The semiconductor device according to claim 4, wherein each of the plurality of boundary trenches has a depth that decreases from the IGBT region toward the diode region.

6. The semiconductor device according to claim 4, wherein among the plurality of boundary trenches, a trench is narrower as the trench is shallower.

7. The semiconductor device according to claim 3, wherein among the plurality of boundary trenches, a trench closest to the diode region is narrower than a trench closest to the IGBT region.

8. The semiconductor device according to claim 7, wherein each of the plurality of boundary trenches has a width that decreases from the IGBT region toward the diode region.

9. The semiconductor device according to claim 3, wherein the plurality of boundary trenches have a pitch different from a pitch of the IGBT trenches.

10. The semiconductor device according to claim 3, wherein a cathode layer is provided on the back surface side of the boundary region of the semiconductor substrate.

11. The semiconductor device according to claim 3, wherein a collector layer is provided on the back surface side of the boundary region of the semiconductor substrate.

12. The semiconductor device according to claim 3, wherein a cathode layer and a collector layer are provided on the back surface side of the boundary region of the semiconductor substrate.

13. The semiconductor device according to claim 3, wherein cathode layers and collector layers are alternately provided on the back surface side of the boundary region of the semiconductor substrate.

14. The semiconductor device according to claim 3, wherein at least one of the plurality of boundary trenches is in contact with an emitter layer.

15. The semiconductor device according to claim 3, further comprising a boundary gate electrode provided inside at least one of the plurality of boundary trenches, wherein
the boundary gate electrode is electrically connected to the front surface electrode.

16. The semiconductor device according to claim 3, further comprising a boundary gate electrode provided inside at least one of the plurality of boundary trenches, wherein
the boundary gate electrode is electrically connected to the IGBT gate electrodes.

17. The semiconductor device according to claim 3, further comprising a boundary gate electrode provided inside at least one of the plurality of boundary trenches, wherein
the boundary gate electrode is electrically independent from the front surface electrode and the IGBT gate electrodes.

18. The semiconductor device according to claim 3, further comprising:
IGBT gate insulating films each formed on an inner wall of a corresponding one of the IGBT trenches;
a boundary gate insulating film formed on an inner wall of at least one of the plurality of boundary trenches; and
a boundary gate electrode provided inside at least one of the plurality of boundary trenches via the boundary gate insulating film, wherein
the boundary gate insulating film is thinner than the IGBT gate insulating films.

19. The semiconductor device according to claim 3, further comprising:
IGBT gate insulating films each formed on an inner wall of a corresponding one of the IGBT trenches;
a boundary gate insulating film formed on an inner wall of at least one of the plurality of boundary trenches; and
a boundary gate electrode provided inside at least one of the plurality of boundary trenches via the boundary gate insulating film, wherein
the boundary gate insulating film is thicker than the IGBT gate insulating films.

20. The semiconductor device according to claim 3, wherein at least one of the plurality of boundary trenches is filled with a dielectric.

21. The semiconductor device according to claim 3, further comprising:
a boundary gate insulating film formed on an inner wall of at least one of the plurality of boundary trenches; and
a boundary gate electrode provided inside at least one of the plurality of boundary trenches via the boundary gate insulating film, wherein
the boundary gate electrode has a protrusion that protrudes upward relative to the boundary gate insulating film, and
the front surface electrode is in contact with an upper surface and a side surface of the protrusion.

22. The semiconductor device according to claim 3, further comprising:
a drift layer of a first conductivity type provided in the semiconductor substrate; and
an electric field relaxation layer of a second conductivity type provided in the drift layer under at least one of the plurality of boundary trenches.

23. The semiconductor device according to claim 3, wherein a ladder trench is formed on an upper surface of the boundary region so as to connect the plurality of boundary trenches in plan view.

24. The semiconductor device according to claim 23, wherein
the plurality of boundary trenches include a first trench and a second trench adjacent to the first trench and narrower than the first trench, and
the ladder trench connecting the first trench and the second trench is narrower on a side of the second trench than on a side of the first trench.

25. The semiconductor device according to claim 3, further comprising a boundary gate electrode provided inside at least one of the plurality of boundary trenches, wherein
the boundary gate electrode is divided into upper and lower parts inside a boundary trench corresponding to the boundary gate electrode.

26. The semiconductor device according to claim 3, wherein
the boundary region is provided so as to surround the diode region in plan view, and
in plan view, at least one of the plurality of boundary trenches has corner portions, along the diode region, each formed with an obtuse angle or a curved surface.

27. The semiconductor device according to claim 3, further comprising:
a drift layer of a first conductivity type provided in the semiconductor substrate; and
an electric field relaxation layer of a second conductivity type provided in the drift layer, under the IGBT trench closest to the diode region in the IGBT region.

28. The semiconductor device according to claim 3, further comprising:
a drift layer of a first conductivity type provided in the semiconductor substrate;
a base layer of a second conductivity type provided on an upper surface side of the drift layer in the IGBT region; and
a carrier accumulation layer of the first conductivity type that is provided deeper than the base layer on an upper surface side of the drift layer in the IGBT region and that is not provided in the diode region.

29. The semiconductor device according to claim 28, wherein a side surface of the carrier accumulation layer closest to the diode region is in contact with any of the plurality of boundary trenches or an anode layer.

30. The semiconductor device according to claim 28, wherein an anode layer is provided to a position deeper than the carrier accumulation layer.

31. The semiconductor device according to claim 3, wherein
an emitter layer and an IGBT contact layer having a higher concentration than the emitter layer are formed on an uppermost surface of the IGBT region,
an anode layer and a diode contact layer having a higher concentration than the anode layer are formed on an uppermost surface of the diode region, and
in plan view, a ratio of an area of the diode contact layer to an area of the diode region is smaller than a ratio of an area of the IGBT contact layer to an area of the IGBT region.

32. The semiconductor device according to claim 3, further comprising a drift layer of a first conductivity type provided in the semiconductor substrate, wherein
a maximum concentration of a layer of a second conductivity type on an uppermost surface of the diode region is lower than a maximum concentration of a layer of a second conductivity type on an uppermost surface of the IGBT region.

33. The semiconductor device according to claim 3, wherein
the front surface electrode is made of a metal containing Al or Ni, and
an upper surface of the diode region is in direct contact with the front surface electrode.

34. The semiconductor device according to claim 3, wherein a plurality of contact holes for causing an upper surface of the diode region to be in contact with the front surface electrode are positioned on the upper surface of the diode region.

35. The semiconductor device according to claim 3, wherein only one contact hole for causing an upper surface of the diode region to be in contact with the front surface electrode is formed on the upper surface of the diode region.

36. A semiconductor device comprising:
a semiconductor substrate having an IGBT region and a diode region, the IGBT region having an upper surface on which one or more IGBT trenches are formed, the diode region having an upper surface on which no trench gate structure is formed;
a front surface electrode provided on an upper surface of the semiconductor substrate;
a back surface electrode provided on a back surface of the semiconductor substrate; and
IGBT gate electrodes provided inside the respective IGBT trenches, wherein
an anode layer of the diode region is provided so as to cover a lower end of a trench provided closest to the diode region among the IGBT trenches.

37. The semiconductor device according to claim 3, wherein the semiconductor substrate is made with a wide band gap semiconductor.

38. The semiconductor device according to claim 37, wherein the wide band gap semiconductor is silicon carbide, gallium-nitride-based material or diamond.
